(19) United States
(12) Patent Application Publication
(10) Pub. No.: US 2023/0212402 A1
(43) Pub. Date: Jul. 6, 2023

(54) TWO DIMENSIONAL SILICON CARBIDE MATERIALS AND FABRICATION METHODS THEREOF

(71) Applicant: UNM RAINFOREST INNOVATIONS, Albuquerque, NM (US)

(72) Inventor: Sakineh CHABI, Albuquerque, NM (US)

(73) Assignee: UNM RAINFOREST INNOVATIONS, Albuquerque, NM (US)

(21) Appl. No.: 17/996,482

(22) PCT Filed: May 10, 2021
(86) PCT No.: PCT/US2021/031560

§ 371 Date: Oct. 18, 2022

Related U.S. Application Data
(60) Provisional application No. 63/029,958, filed on May 26, 2020.

(51) Int. Cl. C09C 3/04; C01B 32/984; C09C 1/28; C23C 16/32

(52) U.S. Cl. CPC C09C 3/04; C01B 32/984; C09C 1/28; C23C 16/325; C01P 2004/61; C01P 2006/12; C01P 2002/52; C01P 2002/77; C01P 2004/24; C01P 2004/04; C01P 2004/02; C01P 2002/85; B82Y 30/00

(57) ABSTRACT

Disclosed is a method for synthesizing two-dimensional (2D) silicon carbide and other materials. The method includes the use of hexagonal SiC precursor in a wet exfoliation technique. The method may also include synthesizing two-dimensional (2D) silicon carbide by a chemical vapor deposition method, or a combination of a liquid exfoliation technique and a chemical vapor deposition method.

### CROSS-REFERENCE TO RELATED APPLICATIONS

This application is a U.S. National Phase application of PCT/US2021/031560 filed May 10, 2021, which claims priority to provisional U.S. Provisional Application No. 63/029,958 filed on May 26, 2020, the disclosures of which are incorporated by reference herein in their entireties.

### FIELD

The present disclosure generally relates to two dimensional materials and methods of forming two dimensional materials.

### BACKGROUND

Since the discovery of graphene in 2004, there has been an increased priority in the development of, two dimensional (2D) semiconductors from different bulk materials. Particular interest has been given to the development of 2D semiconductors with a larger bandgap as compared to graphene, which is nearly zero.

Modern optoelectronic and electronic technologies need to be flexible, lightweight, ultrafast and highly efficient (with minimum power loss). These characteristics cannot be achieved with conventional semiconducting materials such as silicon. Bulk silicon carbide (SiC), by contrast, has many exceptional physical properties, including a wide band gap, high breakdown field, high strength, and high temperature tolerance. It is widely used in high-temperature, high-frequency, and high-power electronics, and as a wide band gap semi conducing material, silicon carbide has an edge over silicon. In addition, SiC benefits from high chemical and thermal stability and it demonstrate a unique ability to resist radiation. These characteristics are critical for its application in extreme electronic environments. However, as a result of its quantum confinement, 2D SIC offers additional opportunities for applications compared to the corresponding bulk material. For instance, 2D SiC may provide unusual physical properties, which are absent in other SiC configurations e.g., bulk SiC or one dimensional SiC.

In the past ten years, research in the field of two-dimensional (2D) materials has transitioned exponentially from fundamental studies to the actual development of complex 2D materials. While an increasing number of van der Waals layered 2D materials, including graphene and boron nitride, have been synthesized successfully on a laboratory scale, others have only been theoretically predicted. One important example is 2D silicon carbide (SiC), which is a covalent layered material in its bulk form. Unlike graphene, whose applications in electronics and optoelectronics are limited by its zero bandgap, the wide bandgap nature of SiC could be effectively employed and optimized in fabricating atomic thick devices such as nanosheet transistors or optoelectronic devices such as LED and solar cells. To date, several predictive calculations, including the density-functional theory (DFT), have suggested that single layer SiC is energetically stable and attainable. Theoretical calculations have predicted that two dimensional SiC (2D-SiC) with a honeycomb structure, similar to graphene and silicene, could be energetically stable. 2D SiC is predicted to possess unprecedented electrical, magnetic, and optical properties (e.g., direct band gap) that could revolutionize the field of semiconducting materials. Structurally, 2D SiC is expected to have a hexagonal honeycomb structure. In the monolayer SiC, the carbon and silicon atoms will bond through sp2 hybrid orbitals to form the SiC sheet. Using the density functional theory, key electronic and optical properties of 2D SiC nanosheets have been investigated. The most important and fascinating electrical property finding is that 2D SiC has a direct wide band bandgap. Various studies have shown that, as the atomic layer interacts with the nearest neighboring layers in 2D-SiC, the band structure changes significantly from monolayer to few-layer SiC. Monolayer 2D-SiC has a direct bandgap of about 2.58 eV that can be tuned through in-plane strain. Alternatively, few-layer 2D-SiC exhibits an indirect bandgap. Electrical properties of 2D SiC are determined basically through its electronic band structure. The band gap can be controlled via in plane strain and dopants. This intriguing property of having a tunable, wide bandgap, is very beneficial to optoelectronic devices such as light-emitting diodes (LEDs) as it allows the fabrication of a variety of LEDs e.g. green, blue, red LEDS.

Further, 2D-SiC has highly tunable magnetic properties. For example, while various allotropic forms of SiC are normally non-magnetic semiconductors, an Si vacancy gives rise to spin polarization. It has been predicted that hydrogenated SiC sheet is a bipolar magnetic semiconductor. This means that the spin polarization of 2D SiC can be created and controlled by a gate voltage, which make it an attractive material for use in spintronic and quantum commuters. The synthesis of 2D SiC is one of the more challenging syntheses among 2D materials, demanding deep understanding of the chemical structure of the bulk SiC materials. The main challenge is that bulk SiC has strong covalent interlayer bonding, as compared to graphene and other layered materials which only have weak van der Waals forces. Given all aforementioned potentials that 2D SiC holds, It would be very useful and desirable to have a method for synthesizing 2D SiC.

### SUMMARY

The following presents a simplified summary in order to provide a basic understanding of some aspects of one or more embodiments of the present teachings. This summary is not an extensive overview, nor is it intended to identify key or critical elements of the present teachings, nor to delineate the scope of the disclosure. Rather, its primary purpose is merely to present one or more concepts in simplified form as a prelude to the detailed description presented later.

A method for forming two-dimensional (2D) silicon carbide (SiC) is disclosed. The method may include providing a plurality of SiC particles, where each of the plurality of SiC precursor has a dimension of about 4 μm or more. SiC particles may be in the form of SiC whiskers, SiC powder, SiC flakes, or a combination thereof. The method for forming two-dimensional (2D) silicon carbide (SiC) may include forming a solution including the plurality of SiC powder and a solvent. The method for forming two-dimensional (2D) silicon carbide (SiC) may include sonicating the solution for about 4 to about 24 hours. The method for forming two-dimensional (2D) silicon carbide (SiC) may further include centrifuging the solution that was sonicated to extract 2D SiC.

The method for forming two-dimensional (2D) silicon carbide (SiC) may include a plurality of SiC whiskers having a surface area of about 8 μm² or more. The plurality of SiC whiskers may have an average length of about 18 μm and an average diameter of about 1.5 μm. The solution may include a ratio of 0.1 mg of SiC particles per 1 ml of solvent or greater. The solvent may include n-methyl-2-pyrrolidone (NMP), isopropyl alcohol (IPA), hexane, methanol, organic solvents, polar solvents, non-polar solvents or combinations thereof. The sonicating of the solution may include adding liquid to the solution being sonicated to compensate for liquid lost during sonication. Centrifuging the solution may include varying the speed from about 500 rpm to about 13000 rpm. A monolayer silicon carbide produced by the method is also disclosed.

A liquid exfoliation method for forming two-dimensional (2D) materials is also disclosed. The liquid exfoliation method also includes providing a precursor material having a plurality of one-dimensional structures. The liquid exfoliation method may include forming a solution of the precursor material and a solvent. The liquid exfoliation method may include sonicating the solution. The liquid exfoliation method also includes centrifuging the solution that was sonicated. The liquid exfoliation method also includes extracting a two-dimensional (2D) material, where the two-dimensional (2D) material may include the same composition as precursor material. Implementations of the liquid exfoliation method may include a ceramic material as a precursor. Implementations of the liquid exfoliation method may include a semiconducting material as a precursor. Implementations of the liquid exfoliation method may include a material with strong covalent interlayer bonding in bulk when compared to graphene as a precursor. The plurality of one-dimensional structures used in the liquid exfoliation method may include whiskers, fibers, or microwires and powder, particles, flakes. The plurality of one-dimensional structures used in the liquid exfoliation method may have a length of 5 μm or more. The plurality of one-dimensional structures used in the liquid exfoliation method may have an average length of about 18 μm or more and an average diameter of about 1.5 μm or more. The plurality of one-dimensional structures used in the liquid exfoliation method may have a surface area of about 8 μm² or more. One or more chemical dopants used in the liquid exfoliation method may include a transition metal, a non-magnetic metal, or combinations thereof.

Another method for forming two-dimensional (2D) silicon carbide (SiC) is disclosed. The method for forming two-dimensional (2D) silicon carbide (SiC) may include providing a carbon-based precursor and exposing the carbon-based precursor to a silicon vapor to produce silicon carbide within a chemical vapor deposition (CVD) process. The method for forming two-dimensional (2D) silicon carbide (SiC) may include forming a solution having the silicon carbide and a solvent. The method for forming two-dimensional (2D) silicon carbide (SiC) may include sonicating the solution, centrifuging the solution that was sonicated, and extracting two-dimensional (2D) silicon carbide (SiC).

The method for forming two-dimensional (2D) silicon carbide (SiC) may also include reacting a carbon-based precursor with the silicon vapor within the CVD process. The carbon-based precursor may include ethanol, styrene, or combinations thereof. The method for forming two-dimensional (2D) silicon carbide (SiC) may also include a stoichiometric ratio of silicon to carbon that is not equal to 1:1. The method for forming two-dimensional (2D) silicon carbide (SiC) may also include a carbon-based precursor including monolayer graphene, bilayer graphene, graphene foam, graphite, foam, or a combination thereof.

### BRIEF DESCRIPTION OF THE DRAWINGS

The accompanying drawings, which are incorporated in and constitute a part of this specification, illustrate the present disclosure and together with the description, serve to explain the principles of the present disclosure.

FIG. 1A schematically depicts the atomic structure of graphite according to the present disclosure.

FIG. 1B schematically depicts the atomic structure of graphene according to the present disclosure.

FIG. 1C schematically depicts the atomic structure of bulk silicon carbide according to the present disclosure.

FIG. 1D schematically depicts the atomic structure of monolayer, or 2D silicon carbide according to the present disclosure.

FIG. 2 is a flowchart illustrating a liquid exfoliation method for synthesizing two-dimensional silicon carbide, according to the present disclosure.

FIG. 3A is a high-resolution TEM image of monolayer SiC according to the present disclosure.

FIG. 3B is a higher magnification TEM image of monolayer SiC according to the present disclosure.

FIG. 3C schematically depicts a hexagonal planar structure of monolayer SiC according to the present disclosure.

FIG. 4A is an optical microscopy image of a plurality of exfoliated SiC nanosheets, fabricated according to the present disclosure.

FIGS. 4B and 4C are atomic force microscopy (AFM) images and a plot illustrating an average height difference between a substrate and a nanosheet of SiC, respectively.

FIG. 4D is a transmission electron microscopy (TEM) image of exfoliated SiC nanosheets, fabricated according to the present disclosure.

FIG. 4E is an energy-dispersive X-ray (EDX) spectrum of the exfoliated SiC nanosheets of FIG. 4D, confirming the composition thereof.

FIGS. 4F and 4G are high resolution TEM images of exfoliated SiC nanosheets, at various magnifications, fabricated according to the present disclosure.

FIGS. 4H and 4I are high resolution TEM images of exfoliated SiC nanosheets, at various magnifications, fabricated according to the present disclosure.

### DESCRIPTION

Reference will now be made in detail to exemplary implementations of the present disclosure, examples of which are illustrated in the accompanying drawings. Wherever possible, the same reference numbers will be used throughout the drawings to refer to the same or like parts. In the following description, reference is made to the accompanying drawings that form a part thereof, and in which is shown by way of illustration specific exemplary implementations in which the present disclosure may be practiced. These implementations are described in sufficient detail to enable those skilled in the art to practice the present disclosure and it is to be understood that other implementations may be utilized and that changes may be made without departing from the scope of the present disclosure. The following description is, therefore, merely exemplary.

Presently, there is a need for a method of synthesizing 2D materials such as silicon carbide. For silicon carbide in particular, there are many differences in structure and properties for 2D silicon carbide (SiC) as compared with bulk silicon carbide. Bulk SiC has strong covalent interlayer bonding, as compared to graphite and other layered materials which only have weak van der Waals forces, rendering the synthesis of 2D silicon carbide more challenging.

The fabrication of hexagonal monolayer silicon carbide using hexagonal SiC particles as a precursor as described herein facilitates the isolation of monolayer SiC from bulk SiC in a liquid exfoliation process. The wet exfoliation process and methods disclosed herein enable the use of various SiC precursor materials, including 6H—SiC particles, SiC whiskers, 4H—SiC, 2H—SiC in this wet exfoliation process. In certain embodiments, whiskers, fibers, or microwires and powder, particles, flakes, or combinations thereof may be used. Methods according to embodiments described herein may also be applicable to other materials to fabricate 2D materials based on other compositions. Liquid exfoliation processes as described herein may also be combined with or complemented by other fabrication methods to create monolayer or 2D materials. For the purposes of this disclosure, two-dimensional silicon carbide, or 2D-SiC, may alternatively be referred to as silicon carbide nanosheets, monolayer silicon carbide, monolayer SiC, few-layer silicon carbide, few-layer SiC, or siligraphene. Furthermore, other two-dimensional materials may also be referred to as 2D, nanosheet, monolayer, or few-layer.

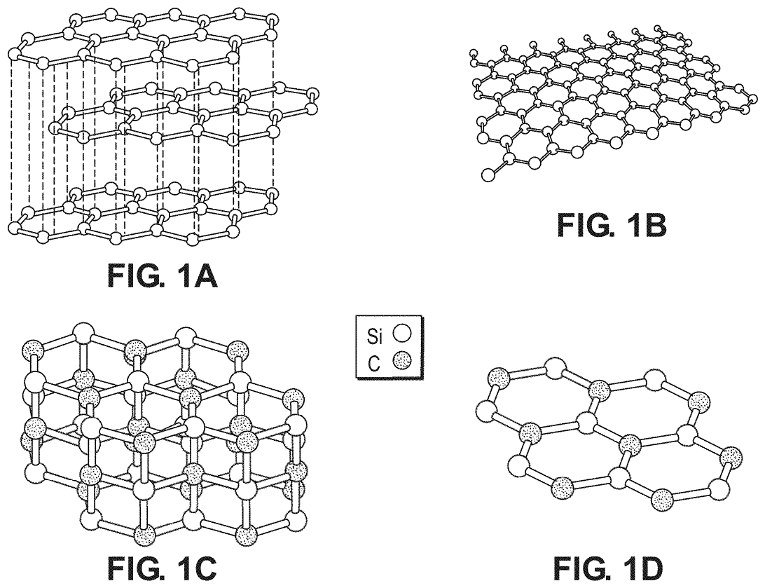

Structurally, 2D SiC has been predicted to have a graphene-like honeycomb structure consisting of alternating Si and C atoms. In 2D or monolayer SiC, the carbon and silicon atoms will bond through sp2 hybrid orbitals to form a SiC sheet, as illustrated in FIG. 1D. Studies related to the stability of planar 2D SiC have confirmed that 2D SiC is energetically stable and has a 100% planar structure with inherent dynamic stability. The compositional and structural properties of 2D SiC result in many attractive material properties. 2D SiC is a wide band gap semiconducting material with a number of potential applications including power electronics, optoelectronics, and spintronics. Unlike many other 2D materials such as silicene, or the 2D form of silicon, 2D SiC is environmentally stable and therefore useful for device fabrication. While Silicon carbide in bulk form may exist in as many as 250 polytypes, monolayer SiC does not have any polytype. Unlike bulk SiC which exhibits an indirect band gap, monolayer SiC has a direct band gap. This feature is important for optoelectronics and photonic applications. As atomic thick wide band gap semiconductor materials, the use of 2D SiC may enable faster, smaller, thinner electronic devices such as 2D SiC switches, nanosheet transistors, and the like. This direct band gap characteristic of 2D SiC may enable its use in several applications such as light emitting diodes, bioimaging, and the like. Depending on the number of layers, for example monolayer vs. bilayer SiC, or few-later SiC, the size of the band gap may vary. Compared to bulk SiC, 2D SiC also exhibits enhanced photoluminescence (PL) properties, non-linear optical properties, and notable mechanical properties. Two-dimensional SiC also has highly tunable electronic, optical, and mechanical properties. For example, optical and electronic properties of 2D SiC can be modified via several methods including chemical functionalization, introducing defects, applying mechanical strain, or combinations thereof. While 2D SiC does not exist in nature, methods as disclosed herein have successfully produced 2D SiC via the wet exfoliation method.

Aside from graphene and hexagonal boron nitride, h-BN, most explored 2D materials do not exhibit stable planar structures. Rather, they stabilize their monolayer structures via a combination of sp3/sp2 bonding resulting in buckling of the crystalline structure. As an example, buckling values of 0.44 Å, 0.65 Å and 2.3 Å have been reported for silicene, germanene, and black phosphorous (BP), respectively. It has been suggested that one potential approach to reducing the buckling level in silicene is to use alternate atoms in place of pure silicon. Thus, as 2D SiC could be considered as a heteroatomic form of silicene, it is reasonable that it would exhibit a stable planar structure.

The stability of monolayer 2D SiC has been studied and confirmed using density functional theory (DFT) calculations to study phase transformation and stability in ultrathin wurtzite SiC, ZnO, GaN, BeO, and AlN films. These studies predicted wurtzite SiC or ZnO structures are thinned down to few atomic layers, they adopt graphitic like structure in which the atoms are threefold coordinated. This prediction was then confirmed experimentally, but only for ultrathin films with ZnO and AlN. Phonon dispersion of 2D SiC and the calculated phonon spectra also support the anticipated stability of 2D SiC. This predicted planarity feature further contributes to the development of several unprecedented properties in 2D materials, particularly those 2D SiC materials.

In addition to the structural advantages of 2D SiC, the key properties of 2D SixCy may be also determined by the Si/C stoichiometric ratio. As a result of different composition, or ratio of Si:C, 2D silicon carbide could be tailored to exhibit a broad range of electronic, optical, magnetic, and mechanical properties. Therefore, alloying carbon and silicon atoms in such a planar two-dimensional binary system offers a high level of capabilities, flexibilities, and functionalities, which are not attainable with the use of other closely related materials such as graphene or silicene.

The electronic properties of 2D silicon carbide materials may be determined through their electronic band structure. The band gap behavior in 2D SiC is thought to be related to the electronegativity differences between silicon and carbon atoms, which would induce electron transfer from valance electrons of silicon to the nearest carbon, resulting in an emerging band gap. Theoretical calculations further predict that monolayer SiC is a direct bandgap semiconductor, which is in contrast with the indirect nature of the band gap in bulk SiC. Again, density functional theory calculations predict that monolayer SiC has a theoretical direct band gap of 2.55 eV. However, the calculated band gap is in the range of 3-4.8 eV when computed with GW quasiparticle corrections, GLLB-SC and other methods of approximation. The indirect-direct band gap transition characteristic in 2D SiC, is similar to the previously reported feature in other 2D materials such as 2D transition metal dichalcogenides (TMDs). This type of indirect-direct band gap transition may be attributed to a lack of any interlayer interactions in the TMDs monolayer. It may be noted that TMDs are van der Waals layered materials similar to graphite, and as such, they can easily be fabricated via mechanical exfoliation.

The electronic properties of 2D silicon carbide depend strongly on the number of layers, as well as the atomic ratio between carbon and silicon in SixCy. The band structure of one to three layers of SiC is expected to experience significant deviation from that of bulk SiC. Alternate stacking sequences, for example, AB or ABC, may exhibit different band structures and thus, different properties. While it is also understood that monolayer SiC has a direct bandgap, multilayer SiC has been found to have an indirect bandgap, and therefore an indirect-direct band gap crossover is possible for up to three layered SiC. This band gap crossover, which reaches its limit in monolayer SiC, may be attributed to the reduced dimensionality and electronic confinement in the direction perpendicular to the c axis. The bandgap of few layer silicon carbide is expected to decrease as the number of layers increases. The latter can be attributed to the reduced dielectric screening in monolayer silicon carbide.

The atomic ratio between carbon and silicon in 2D SixCy, the effects of the edge structure (armchair or zigzag), structural defect levels, mechanical strain, and chemical doping may also influence the size of the bandgap and carrier mobility within 2D silicon carbide. Therefore, 2D silicon carbide materials, SixCy, may benefit from highly tunable electronic properties. The band structure can be controlled by varying the Si:C composition, mechanical strain, and defects. This modifiability provides significant advantages as enables the use of 2D silicon carbide for a variety of applications.

Unlike bulk silicon carbide which is an indirect semiconductor with weak absorption and light emitting characteristics, 2D silicon carbide has very rich optical properties such as strong photoluminescence, and excitonic effects, as a result of its direct bandgap and quantum confinement effects. The optical absorption spectra of 2D silicon carbide are shown to vary depending on light polarization, number of the layers, and Si/C ratio in SixCy structures. Light polarization due to the 2D SiC highly anisotropic optical properties.

Optical properties of 2D silicon carbide, such as absorption flux, exciton binding energy, optical conductivity, are also strongly affected by the atomic ratio between carbon and silicon. Depending on the compositions, SixCy materials have different band structures and thus band gap. As discussed earlier, among SixCy materials, 1:1 stoichiometry, i.e., SiC is expected to have the largest band gap. Theoretical studies have also reported that 2D silicon carbide has strong nonlinear optical properties. The nonlinear optical properties in silicon carbide materials, are also affected by the atomic ratio between C and Si. For example, it was reported that carbon-rich SixCy materials, in bulk silicon carbide, have been shown to exhibit enhanced nonlinear refractive index as compared to more silicon-rich materials. This enhancement may be attributed to an increased saturable absorbance in carbon-rich materials as a result of delocalized p-electrons.

While bulk SiC is considered a candidate of interest for use in applications requiring materials having magnetism and spintronic properties, the expected properties of 2D SiC are also of interest. Perfect monolayer planar SiC is known to be a non-magnetic semiconductor, and other forms of 2D SiC including defect-contained monolayer are known to exhibit magnetism behavior. Theoretical studies have found that the magnetic properties of 2D SiC can be tuned through doping, structural defects, mechanical strain, or combinations thereof. Suitable chemical dopants may include transition metals (TMs) or non-magnetic metals (NMMs) in order to tune magnetism behavior of 2D SiC. Structural defects may be introduced into 2D materials to engineer magnetic properties of 2D materials via the incorporation of vacancy defects. This approach has been used successfully in manipulating magnetism and spin fluctuations in graphene. In 2D SiC, three types of vacancy defects have been studied—single C or Si vacancy, Si+C divacancy, and Si—C anti-site defects in the monolayer. The aforementioned defects may be grown during the synthesis or surface defects may be introduced during fabrication to introduce magnetism or ferromagnetism behavior in monolayer SiC or other 2D materials as described herein.

It has been also reported that as the thickness of SiC nanosheets decreases, for example, from 9 to 3 nm, the saturation magnetization also increases. The observed magnetism may be related to defects with carbon dangling bond on the surface of nanosheets. Mechanical strain may also be used to tune magnetic properties of these materials, for example, with the introduction of compressive strain, in order to transform 2D SiC from a semi-conductor to a metal. Similar switchable magnetism has been observed in Mn-doped 2D SiC as well. This flexibility and modifiability of 2D SiC, acting as a ferromagnetic material at RT, is very useful for applications such as magnetic memories, magnetic storage and communications technology devices.

The mechanical properties of any material are determined by its in-plane and out of plane atomic bonding. Silicon carbide is one of the strongest known materials due to the strong covalent bonding of silicon and carbon. Similar to bulk SiC, 2D SiC is a brittle material and a sudden drop in the stress at high strain has been predicted. As compared to bulk SiC, which is a covalently bonded material along both c-axis and a-axis, monolayer silicon carbide is a single atom thick material, having no c-axis. As such, 2D SiC is expected to have different mechanical properties than bulk SiC. Theoretical studies indicate that 2D SiC may have anisotropic mechanical properties as well. Mechanical properties of 2D SiC, such as Young's modulus, in-plane stiffness, and toughness, can be strongly influenced by the structure of the edges, i.e., armchair or zigzag, and their orientations, as well as the atomic ratio between Si and C in SixCy.

Due to the direct band gap properties of 2D SiC has great potential use in optoelectronic applications, such as light emitting diodes (LEDs), lasers, optical switches and solar cells. Monolayer or 2D silicon carbide, as described herein, also exhibits a tunable bandgap and a bright emission which is a useful property for engineering the optoelectronic response for the aforementioned applications. This flexibility in band gap alteration enables the fabrication of light emitting devices such as LEDs covering the entire visible spectrum. In addition to its tunable band gap, monolayer silicon carbide has a large exciton energy as a result of enhanced electron-hole interaction and reduced dielectric screening, which is also useful for optoelectronic applications. Large exciton binding energy leads to strong and long-lived excitons, thus making such materials indispensable for applications such as UV excitonic lasers. This property is desired for LEDs, photo markers and excitonic solar cells. Furthermore, 2D SiC can be useful in combination with other materials to enable a variety of highly efficient heterostructures for solar cell components, bioimaging and biosensor applications, cellular imaging, and transport applications.

As a one atom thick wide bandgap material, 2D SiC has potential for electronic devices, particularly in applications or devices benefitting from operation under high temperature, high-power, and high-frequency conditions. Since monolayer silicon carbide is only one atom thick, SiC electronics may exhibit (i) reduced ohmic resistance as a result of reduced thickness and (ii) smaller, lighter nanoelectronics devices. Another advantage is that unlike bulk SiC, which has more than 250 polytypes, monolayer SiC does not have any polytype. The elimination of stacking sequences makes the device fabrication process less complicated.

Depending on the composition, 2D SixCy may behave as semiconductor, with approximate bandgap ranging from 0.0 to 4.0 eV, topological insulator or semimetal. This flexibility further expands the realm of 2D SiC, allowing it to be used for both high and low frequency electronic devices. 2D SiC materials can also be used along with other 2D materials to make a variety of 2D materials-based heterostructure devices by combining graphene or h-BN materials with 2D SiC when conductor or insulator (gate) are needed, respectively. Further still, compared to 2D materials other than graphene and h-BN, monolayer 2D SiC has higher in-plane stiffness and Young's Modulus rendering it beneficial for use in electromechanical devices. 2D SiC may also be used for quantum spintronics as well. Spintronic refers to spin-based electronics that rely on spin-controlled electronic properties. Silicon carbide materials offer such as spins associated with color centers with long coherence times as compared to diamond. 2D SiC, as compared to bulk SiC, offers an additional degree of freedom, allowing some control over the magnetic properties. As described earlier, 2D SiC has highly tunable magnetic properties enabling additional advantages for use in spintronic applications.

The synthesis of 2-dimensional (2D) silicon carbide is challenging because bulk silicon carbide does not have a layered structure, as does bulk graphite, as illustrated in FIG. 1A. Monolayer graphite, i.e., graphene, as illustrated in FIG. 1B, and monolayer hexagonal boron nitride h-BN have been easily synthesized via liquid exfoliation method, because bulk graphite, and bulk BN have layered structures held together by weak van der Waals forces. In the case of silicon carbide and other non-layered materials, although liquid exfoliation method has been used previously, it has not successfully lead to the creation of monolayer materials. The primary reason behind this failure is thought to be a result of the crystal structure and geometry of the starting materials. It may be desirable that SiC precursors be large enough, for example, having a minimum area of 20 μm² to tolerate the exfoliation and centrifugation process. Otherwise, the synthesis process may be unsuccessful. Furthermore, bulk SiC is known to exist in more than 250 polytypes, not all of which are suitable precursor for 2D SiC synthesis. Hexagonal SiC precursor may be preferred for use in the fabrication of 2D SiC. For the purposes of this disclosure, 2-dimensional silicon carbide or 2D SiC may also refer to a single layer SiC or SiC nanosheets up to a few layer (thickness less than 1 nm).

FIG. 1C schematically depicts the atomic structure of bulk silicon carbide, showing its dissimilarity as compared to graphite in terms of the layered structure of graphite. FIG. 1D schematically depicts the atomic structure of monolayer, or 2D silicon carbide and is representative of its predicted planarity. According to the present disclosure, a method of forming monolayer silicon carbide using hexagonal 6H—SiC powder and SiC whiskers as precursor is provided. The average length of these whiskers is can be about 4 μm or more, about 5 μm or more, or about 18 μm or more and have an average diameter of about 1.5 μm. In order for the liquid exfoliation to be successful, the starting SiC materials should be large enough to tolerate the liquid exfoliation process. In certain embodiments, hexagonal SiC e.g., 6H—SiC whiskers may be used in this wet exfoliation process.

According to the present disclosure, one of the dimensions of the SiC whisker (or any other SiC starting materials) should ideally be longer than 5 microns. In other embodiments, any SiC precursors (e.g. whiskers, microwires, flakes, particles or other SiC powders) with an average surface area larger than 8 μm² can be used. The disclosed method can also be used to create monolayer materials from other bulk materials that do not have van der Waals layered structure, for example, ceramic materials. In addition to whiskers, other one-dimensional structures such as fibers or microwires can also be used as starting materials for the synthesis of monolayer structure from non-layered materials. In the case of silicon carbide, not only silicon carbide whiskers, but SiC microwires can be used as starting materials. Similarly, a silicon monolayer might also be produced via liquid exfoliation of silicon microwire. In both cases, the interaction between the solvent and the synthesized sheet plays a key role in the stabilization of the monolayer. Usually, the solvent (e.g. NMP) create a solvation shell around the synthesized sheet and protect it from oxidation.

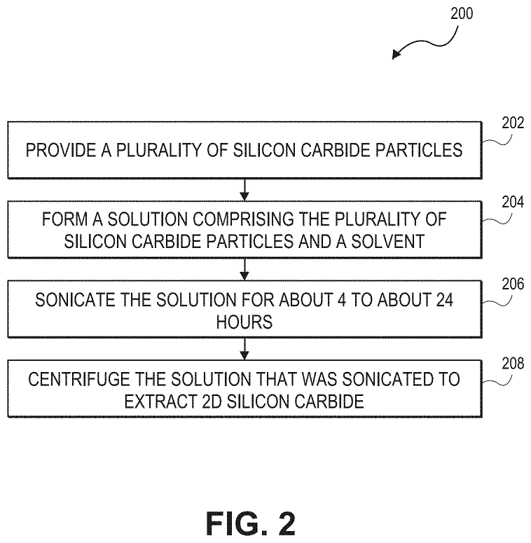

FIG. 2 is a flowchart illustrating a liquid exfoliation method for synthesizing two-dimensional silicon carbide, according to the present disclosure. At 202 of method 200, a plurality of SiC whiskers are provided and used as precursor. The plurality of SiC particles may have a dimension of about 4 μm or more, and the plurality of SiC particles may have a surface area of about 8 μm² or more. The plurality of SiC particles may have an average length of about 18 μm and an average diameter of about 1.5 μm. At 204 of method 200, the plurality of SiC particles are diluted in a solvent. The ratio of SiC particles to solvent can be about 1 mg per 10 ml of solvent or greater. A ratio of 1 mg of SiC particles per 1 ml of solvent or greater may be used in 204, and suitable solvents may include N-methyl-2-pyrrolidone (NMP), isopropyl alcohol (IPA), hexane, methanol, organic solvents, polar solvents, non-polar solvents or combinations thereof. At 206 of method 200, the exfoliation process is started by sonicating the solution of SiC whiskers and solvent for 4 or 24 hours. Liquid may be added to the solution to maintain a constant volume during the sonicating of the solution of SiC and solvent for 4 or 24 hours to compensate for any liquid lost during sonication. At 208 of method 200, centrifuging the solution of SiC particles and solvent is done to extract 2D SiC. Centrifuging the solution of SiC and solvent 208 may be conducted by varying a centrifugation speed from about 500 rpm to about 13000 rpm. A two-dimensional (2D) silicon carbide may be produced by the method as described in regard to FIG. 2. In certain embodiments, the SiC precursor materials or particles may alternatively include whiskers, fibers, microwires, powder, particles, flakes, or combinations thereof.

Two-dimensional silicon carbide, both monolayer and a few layers, were synthesized for the first time via a top-down liquid exfoliation approach. A plurality of SiC whiskers were provided and used as precursor. SiC whiskers were purchased from BeanTown Chemical, Hudson, N.H. The plurality of SiC whiskers were diluted in a solvent, for example, N-methyl-2-pyrrolidone (NMP) or isopropyl alcohol (IPA), both purchased from Sigma Aldrich, with a ratio of 0.1 g in 15 ml solvent in a glass vial. The ratio of whiskers to solvent can be about 0.1 mg per 10 ml of solvent or greater. To start the exfoliation process, the vials of SiC whiskers and solvent were sonicated for 4 or 24 hours in a Branson 5800 Ultrasonic Cleaner, ensuring that to compensate for the water lost in the process due to the increased temperature by adding more to the water basin, keeping it at 1000 ml. It appears that increasing in sonication time decreases the overall size of the final SiC thin flakes. This was followed by centrifugation using an Eppendorf Centrifuge 5425. For the centrifugation process, a sample of 2 ml was obtained from the 15 ml sample is collected via pipettes to a microtube. This was done at different speeds varying from 1k revolutions per minute (rpm) to 13k rpm for different samples, for varying times from 5-20 minutes. Following this, the supernatant of the 2 ml tube (roughly the ⅓ top of it) was collected, here the exfoliated few layered SiC flakes are suspended, and the thicker flakes and the bulk SiC residue are left behind, enabling the extraction of 2D silicone carbide. In certain embodiments according to the present disclosure, centrifugation speeds of from about 500 rpm to about 20k rpm, or from about 2k rpm to about 15k rpm may be used. Furthermore, centrifugation times of from about 1 minute to about 30 minutes, or from about 5 minutes to about 20 minutes may be used. In addition to sonication bath, a sonication probe (i.e ultrasonic) may also be used.

It is also of note to mention that in addition to NMP and IPA, methanol, other polar or non-polar organic solvents e.g., hexane, DMF, toluene, can also be used to make 2D SiC. Further, wet etching such as HF etching can also be used.

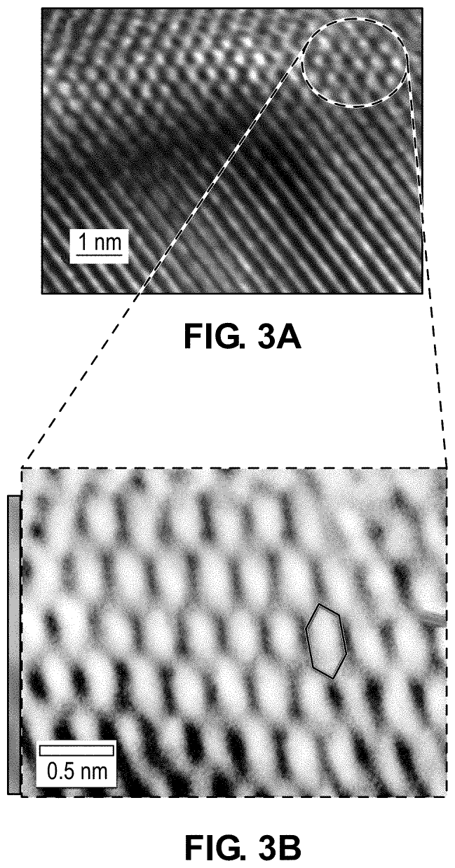

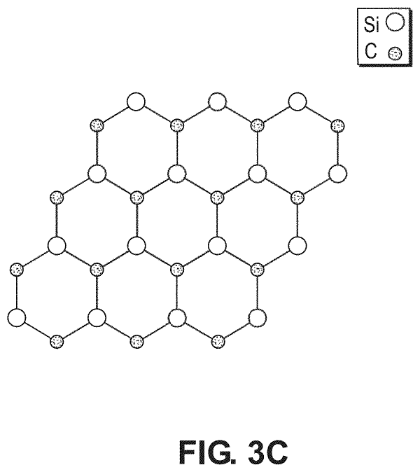

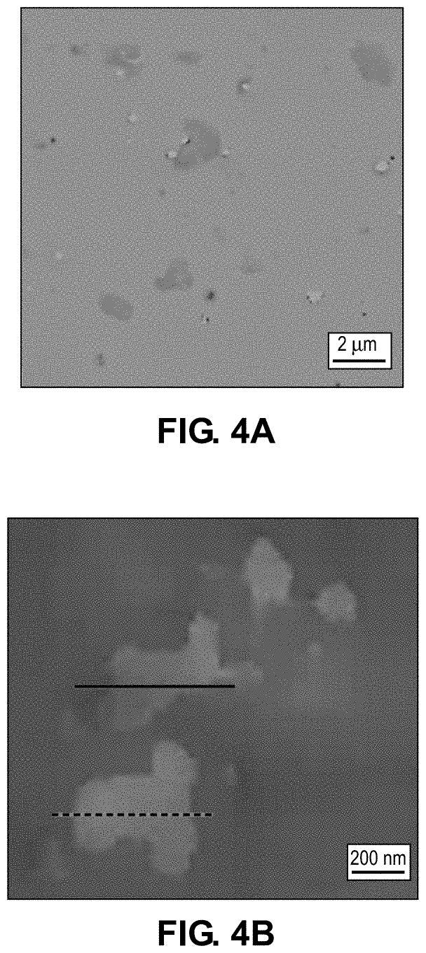

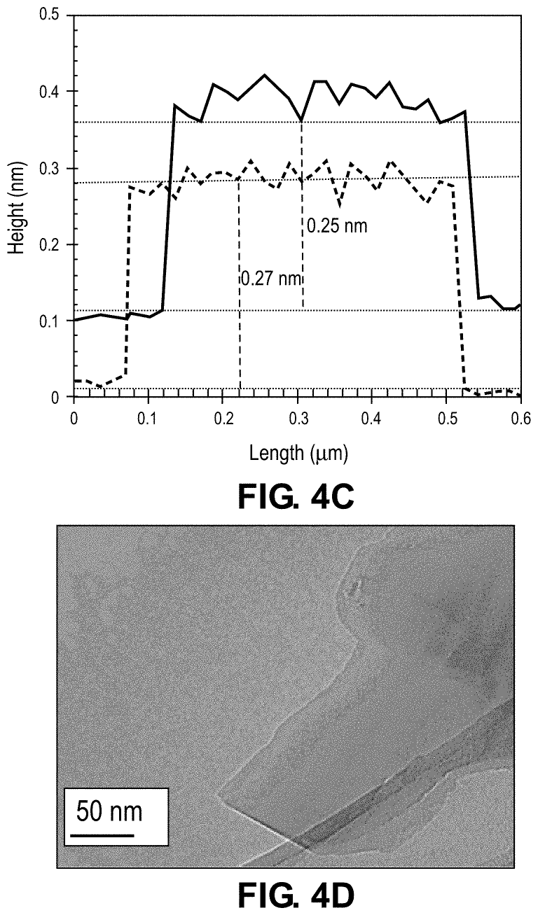

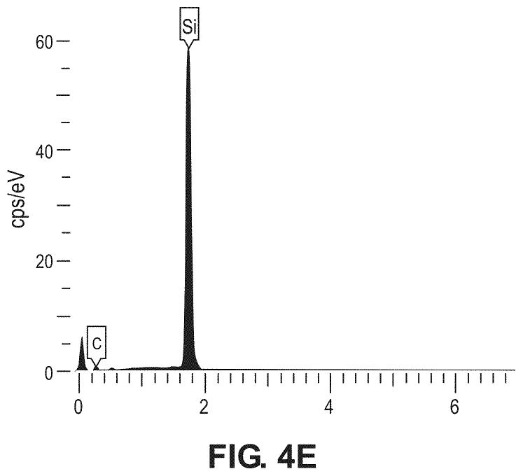

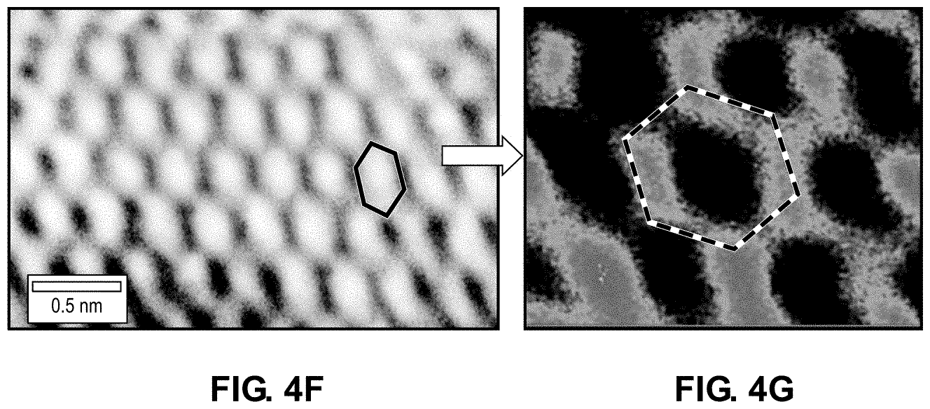

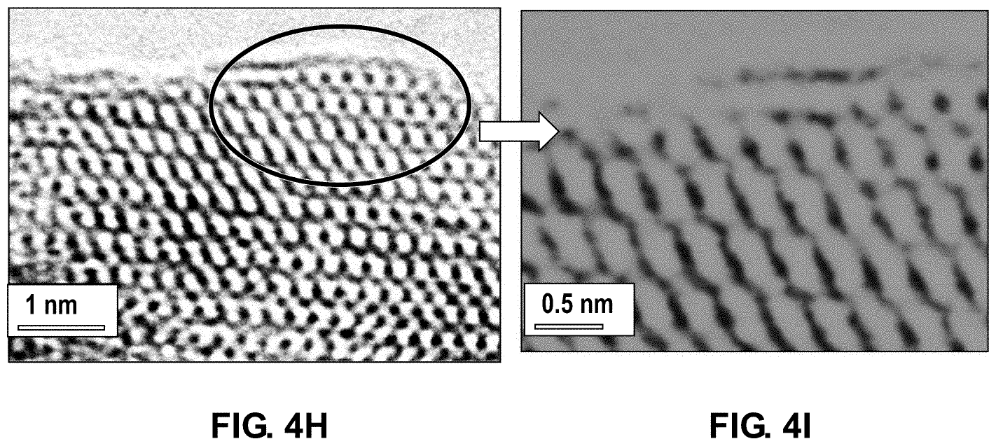

Characterization: The structure of the 2D SiC was studied with a transmission electron microscope (TEM) using STEM and HRTEM mode (JEOL 2010F operating at 200 kV) with the samples on top of a holey carbon grid. To deposit the samples on top of a holey carbon film copper grid, the copper grid was placed above filter paper and the samples from the centrifuge supernatant were drop casted above the copper grid with about 10 drops with a pipette. The copper grid was air dried (heat damages the TEM carbon grid) inside a fume hood overnight. FIG. 3A show a high-resolution TEM image of a 2D SiC, FIG. 3B shows a higher magnification TEM image showing the creation of a SiC monolayer, and FIG. 3C shows a predicted hexagonal planar structure of a SiC monolayer, comparable to the schematic of FIG. 1D. Further characterization of exfoliated SiC nanosheets, fabricated according to methods described herein, are described in regard to FIGS. 4A-4I. FIG. 4A is an optical microscopy image of a plurality of exfoliated SiC nanosheets, fabricated according to the present disclosure. A scale bar of 2 μm illustrates and approximate dimension of the produced exfoliated SiC nanosheets. FIGS. 4B and 4C are atomic force microscopy (AFM) images and a plot illustrating an average height difference between a substrate and a nanosheet of SiC, respectively. The results taken from the AFM image demonstrate that the thicknesses associated with the nanosheets measured at the solid line and the dotted line are 0.25 nm and 0.27 nm, respectively, confirming the monolayer nature of the presented nanosheets. It is also of note that d-spacing between adjacent SiC layers is also about 0.25 nm. FIG. 4D is a transmission electron microscopy (TEM) image of exfoliated SiC nanosheets, fabricated according to the present disclosure. FIG. 4E is an energy-dispersive X-ray (EDX) spectrum of the exfoliated SiC nanosheets of FIG. 4D, confirming the composition thereof. The results shown in FIG. 4E demonstrate the silicon carbide nature of the nanosheet, thereby confirming the composition of the fabricated nanosheet. FIGS. 4F and 4G are high resolution TEM images of exfoliated SiC nanosheets, at various magnifications, fabricated according to the present disclosure. FIGS. 4H and 4I are high resolution TEM images of exfoliated SiC nanosheets, at various magnifications, fabricated according to the present disclosure. The various magnifications shown in the images of FIGS. 4F-4I further demonstrate the hexagonal structure as represented in FIG. 3C.

According to the present disclosure, another method of forming monolayer silicon carbide using chemical vapor deposition (CVD) process of silicon on a carbon-based precursor such as monolayer graphene is provided. The CVD reaction between graphene and silicon precursor can be carried out at 1300-1600 C under argon (Ar) atmosphere. Synthesis time can vary from half an hour to 3 h. Argon flow rate can vary from 50 sccm to 500 sccm, or higher. First, the Si vapor travels downward to reach the surface of the graphene precursor where it reacts with active carbon (C), for example, at the edge boundaries, to form a SiC nucleus. Then, those nuclei grow, across the breadth of the graphene, and result in the formation of 2D SiC. As graphene is a monolayer of carbon, expositing it to silicon vapor either from silane gas or other SiC precursors such as SiO will produce monolayer SiC.

Alternate materials may be used as substrate for CVD synthesis of 2D SiC, such as tungsten foil, magnesium (Mg (0001)), copper foil, and silver. Other materials with melting points higher than the synthesis temperature may also be used. A good lattice match between the substrate and SiC is an important for the successful synthesis of 2D SiC. Monolayer SiC can also be achieved by exposing monolayer silicon to carbon precursor. According to the present disclosure, another method of forming monolayer silicon carbide using chemical vapor deposition (CVD), as described previously, in combination with wet exfoliation of the products of a chemical vapor deposition process. In addition to monolayer graphene other carbon-based precursor materials may also be used for CVD synthesis of SiC in a combined process of CVD with wet exfoliation such as bilayer graphene, a few-layer graphene, graphene foam, and graphite film or foam. In this method, for example, a few or multilayer SiC may first be prepared via CVD reaction between graphene or graphite and silicon vapor. Then wet exfoliation process using parameters as described previously may be used to isolate 2D SiC from multilayer SiC. According to the present disclosure, another method of forming or fabricating 2D SiC uses chemical vapor deposition with the use of both carbon precursors and silicon precursors. Carbon-based precursors such as ethanol, styrene, or combinations thereof may be concurrently introduced into a chemical vapor deposition process along with and silicon vapor, silane gas, SiO, or combinations thereof. In this method, the employed substrate should be selected carefully. The following materials can be used as substrate for CVD synthesis of 2D SiC:Tungsten foil, Mg (0001), copper foil, and Ag, can be used as substrate for this synthesis. Other materials with melting points higher than the synthesis temperature (which is 1300-1600 C) may also be used. A good lattice match between the substrate and SiC is an important for the successful synthesis of 2D SiC.

Furthermore, the concentration of both precursors should be kept low to avoid the formation of thick SiC films. Depending on the size of the substrate different amount (flow rate) of carbon and silicon might be required, however mass ratio of 1:1 would probably ensure the formation of SiC. This method for forming monolayer silicon carbide (SiC) may include the use of or providing a carbon-based precursor. The carbon-based precursor may be in solid form, such as a monolayer graphene, bilayer graphene, graphene foam, graphite, foam, or a combination thereof. Alternatively, the carbon-based precursor may be gaseous and reacted with the silicon vapor within the CVD process, in the form of ethanol, styrene, or a combination thereof. Carbon precursor may be in the form of gaseous, liquids and solids. Example includes, graphite, methane, acetylene, ethylene, benzene, pyridine, styrene, and ethanol. As a result of this method, the stoichiometric ratio of silicon to carbon may or may not be equal to 1:1, according to the desired properties of the formed 2D monolayer material. Subsequent to the carbon-based precursor being exposed to a silicon vapor to produce silicon carbide within a chemical vapor deposition (CVD) process, a solution is formed including the silicon carbide and a solvent. This solution is then sonicated, centrifuged, and finally the monolayer SiC may be extracted from the centrifuged solution.

Hydrogen may also be used along with argon for CVD synthesis of 2D SiC. In addition to 2D SiC, other compositions of silicon carbide i.e SixCy might be achieved by playing with the mass/volume ration between carbon and silicon precursor. For Si-rich SixCy, the flow rate, or mass of silicon precursor should exceeds that's of carbon, and for carbon rich SixCy, the concentration, flow rate of carbon precursor should be larger than that of silicon precursor.

Additional methods for fabricating or producing 2D SiC are provided. These methods include hydrofluoric acid (HF) etching of SiC precursors, chemical vapor deposition (CVD) combined with mechanical exfoliation and transferring of 2D SiC onto a variety of substrates. These methods may be used in combination with one another or with one or more of the previously described methods for producing 2D SiC. In the case of HF etching of SiC precursors, bulk SiC may be etched using HF to produce 2D SiC. In the method of producing SiC via a combination of CVD and mechanical exfoliation, first multilayer or few-layer SiC, or SiC foam, may be prepared via a previously known CVD method, followed by mechanical exfoliation to isolate monolayer SiC from multilayer or few layer SiC. This method may prove more effective on nano atomic thick SiC nanosheets. In the case of transferring 2D SiC onto a variety of substrates, such as silicon wafer, glass slides, sapphire substrate, metal substrates such as copper, indium foil, and aluminum foil. This method includes placing one drop of 2D SiC dispersions on the substrate. Other approaches for transferring 2D SiC include bringing the substrate in contact with a 2D SiC dispersion. For example, different substrates such as silicon wafer may be dipped in a dispersion solution of 2D SiC. Alternatively, in the case of CVD synthesis of monolayer SiC, the substrate can be etched away after synthesis. In certain embodiments, in the case of a CVD-grown monolayer SiC, the created SiC may be transferred to substrates using already established methods for graphene transfer such as polymer supportive layer-based transfer.

While the present teachings have been illustrated with respect to one or more implementations, alterations and/or modifications can be made to the illustrated examples without departing from the spirit and scope of the appended claims. For example, it will be appreciated that while the process is described as a series of acts or events, the present teachings are not limited by the ordering of such acts or events. Some acts may occur in different orders and/or concurrently with other acts or events apart from those described herein. For example, steps of the methods have been described as first, second, third, etc. As used herein, these terms refer only to relative order with respect to each other, e.g., first occurs before second. Also, not all process stages may be required to implement a methodology in accordance with one or more aspects or implementations of the present teachings. It will be appreciated that structural components and/or processing stages can be added or existing structural components and/or processing stages can be removed or modified. Further, one or more of the acts depicted herein may be carried out in one or more separate acts and/or phases. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. As used herein, the term “one or more of” with respect to a listing of items such as, for example, A and B, means A alone, B alone, or A and B. The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “about” indicates that the value listed may be somewhat altered, as long as the alteration does not result in nonconformance of the process or structure to the illustrated implementation. Finally, “exemplary” indicates the description is used as an example, rather than implying that it is an ideal. Other implementations of the present teachings will be apparent to those skilled in the art from consideration of the specification and practice of the disclosure herein. It is intended that the specification and examples be considered as exemplary only, with a true scope and spirit of the present teachings being indicated by the following claims.

What is claimed is:

1. A method for forming two-dimensional (2D) silicon carbide (SiC) comprising:
providing a plurality of SiC particles, wherein each of the plurality of SiC particles has a dimension of about 4 μm or more;
forming a solution comprising the plurality of SiC particles and a solvent;
sonicating the solution for about 4 to about 24 hours; and
centrifuging the solution that was sonicated to extract 2D SiC.

2. The method of claim 1, wherein each of the plurality of SiC particles has a surface area of about 8 μm² or more.

3. The method of claim 1, wherein the plurality of SiC particles comprises an average length of about 18 μm and an average diameter of about 1.5 μm.

4. The method of claim 1 wherein the solution comprises a ratio of 0.1 mg of SiC particles per 1 ml of solvent or greater.

5. The method of claim 1, wherein the solvent comprises N-methyl-2-pyrrolidone (NMP), isopropyl alcohol (IPA), hexane, methanol, organic solvents, polar solvents, non-polar solvents or combinations thereof.

6. The method of claim 1, wherein sonicating the solution further comprises adding liquid to the solution being sonicated to compensate for liquid lost during sonication.

7. The method of claim 1, wherein centrifuging the solution further comprises varying a speed from about 500 rpm to about 13000 rpm.

8. A two-dimensional (2D) silicon carbide produced by the method of claim 1.

9. A liquid exfoliation method for forming two-dimensional (2D) materials comprising:
providing a precursor material comprising a plurality of one-dimensional structures;
forming a solution comprising the precursor material and a solvent;
sonicating the solution; and
centrifuging the solution that was sonicated; and
extracting a two-dimensional (2D) material, wherein the two-dimensional (2D) material comprises a same composition as precursor material.

10. The method of claim 9, wherein the precursor material is a ceramic material, a semiconducting material or a material with strong covalent interlayer bonding in bulk when compared to graphene.

11. The method of claim 9, wherein the plurality of one-dimensional structures comprises whiskers, fibers, microwires, powder, particles, flakes, or combinations thereof.

12. The method of claim 9, wherein the plurality of one-dimensional structures comprise a length of 5 μm or more.

13. The method of claim 9, wherein the plurality of one-dimensional structures comprise an average length of about 18 μm or more and an average diameter of about 1.5 μm or more.

14. The method of claim 9, wherein the plurality of one-dimensional structures comprise a surface area of about 8 μm² or more.

15. The method of claim 9, further comprising introducing one or more chemical dopants into the two-dimensional (2D) material, wherein the one or more chemical dopants comprise a transition metal, a non-magnetic metal, or combinations thereof.

16. A method for forming two-dimensional (2D) silicon carbide (SiC), comprising:
providing a carbon-based precursor;
exposing the carbon-based precursor to a silicon vapor to produce silicon carbide within a chemical vapor deposition (CVD) process;
forming a solution comprising the silicon carbide and a solvent;
sonicating the solution;
centrifuging the solution that was sonicated; and
extracting two-dimensional (2D) SiC.

17. The method of claim 16, wherein the carbon-based precursor further comprises reacting the carbon-based precursor with the silicon vapor within the CVD process.

18. The method of claim 17, wherein the carbon-based precursor comprises ethanol, styrene, or combinations thereof.

19. The method of claim 17, wherein a stoichiometric ratio of silicon to carbon is not equal to 1:1.

20. The method of claim 16, wherein the carbon-based precursor comprises monolayer graphene, bilayer graphene, graphene foam, graphite, foam, or a combination thereof.
